(19) United States
(12) Patent Application Publication
(10) Pub. No.: US 2019/0327844 A1
(43) Pub. Date: Oct. 24, 2019

(54) CONVERTER

(71) Applicant: DELTA ELECTRONICS, INC., Taoyuan City (TW)

(72) Inventors: Yi-Heng SUN, Taoyuan City (TW); Yung-Jen CHENG, Taoyuan City (TW); Kai-Ti CHANG, Taoyuan City (TW)

(21) Appl. No.: 16/381,739

(22) Filed: Apr. 11, 2019

Related U.S. Application Data
(60) Provisional application No. 62/659,380, filed on Apr. 18, 2018.

(30) Foreign Application Priority Data
Jan. 11, 2019 (CN) 201910028580.8

(51) Int. Cl. H05K 5/02; H02M 7/00; H05K 5/06; H05K 5/03

(52) U.S. Cl. CPC H05K 5/0217; H05K 5/03; H05K 5/069; H02M 7/003

(57) ABSTRACT

A converter is provided. The converter includes a housing, a slot, a cover, a connection arm and a shaft. The housing includes a housing inner wall. The slot is disposed on the housing inner wall. The connection arm is connected to the cover. The shaft is disposed on the connection arm, wherein the shaft is rotatably connected to the slot, and is adapted to slide in the slot.

### CROSS REFERENCE TO RELATED APPLICATIONS

This application claims the benefit of U.S. Provisional Application No. 62/659, 380, filed Apr. 18, 2018, the entirety of which is incorporated by reference herein.

This Application claims priority of China Patent Application No. 201910028580.8, filed on Jan. 11, 2019, the entirety of which is incorporated by reference herein.

### BACKGROUND OF THE INVENTION

### Field of the Invention

The present invention relates to a converter, and in particular to a converter with a housing and a rotatable cover.

### Description of the Related Art

A conventional converter includes a housing and a cover. A display panel or a control panel is disposed on the cover. A mainboard and electronic components are disposed inside the housing. The display panel is electrically connected to the mainboard via connection cables. The conventional cover is affixed to the housing with bolts. When maintenance staff detach the cover from the housing, the connection cables may be pulled and damaged, which can be bothersome.

The conventional converter also has a waterproof housing. The waterproof housing includes an additional connection plate, and waterproof joints are affixed to the connection plate. A waterproof washer ring is required to be disposed between the connection plate and the housing, and the waterproof joints are affixed to the connection plate via nuts. The structure of the conventional waterproof housing is complex, and increasing the cost and the time needed for assembly.

### BRIEF SUMMARY OF THE INVENTION

In one embodiment, a converter is provided. The converter includes a housing, a slot, a cover, a connection arm and a shaft. The housing includes a housing inner wall. The slot is disposed on the housing inner wall. The connection arm is connected to the cover. The shaft is disposed on the connection arm, wherein the shaft is rotatably connected to the slot, and is adapted to slide in the slot.

In one embodiment, when the cover is in a closed orientation relative to the housing, the shaft is in a first shaft position inside the slot, and when the cover is in an open orientation relative to the housing, the shaft is in a second shaft position inside the slot.

In one embodiment, the slot is inside the housing completely.

In one embodiment, the shaft is integrally formed on the connection arm.

In one embodiment, the shaft comprises a shaft rib, the slot comprises a slot restriction portion, and when the cover is in the open orientation relative to the housing, the shaft is in the second shaft position inside the slot, and the slot restriction portion is adapted to abut the shaft rib to restrict the movement of the cover.

In one embodiment, the connection arm comprises a connection arm protrusion, the slot comprises a slot abutting portion, and while the cover is rotating from the closed orientation to the open orientation relative to the housing, the connection arm protrusion sequentially abuts the slot abutting portion and is separated from the slot abutting portion.

In one embodiment, the slot comprises a slot stopper, a first slot side wall, a second slot side wall and a slot bottom wall, the slot stopper is connected to the first slot side wall, the second slot side wall and the slot bottom wall, and when the shaft is disposed in the slot, the slot stopper is adapted to restrict the shaft to prevent the shaft from being out from the slot.

In one embodiment, the slot further comprises a guiding portion, the guiding portion is disposed on the slot stopper and perpendicular to the slot stopper, the guiding portion has a guiding inclined surface, and during assembly, the shaft is guided by the guiding inclined surface to slide into the slot.

In one embodiment, the connection arm comprises a first section part and a second section part, the first section part is connected to the second section part, a first extending direction of the first section part differs from a second extending direction of the second section part, and the shaft is disposed on the second section part.

In one embodiment, the connection arm further comprises a guiding curved surface, the guiding curved surface is disposed on the first section part, and while the cover is being rotated from the open orientation to the closed orientation relative to the housing, the guiding curved surface abuts the housing.

In one embodiment, the converter further comprises an interface board, a mainboard and a connection cable, the mainboard is disposed in the housing, the interface board is affixed to the cover, and the interface board is electrically connected to the mainboard via the connection cable.

In one embodiment, the housing further comprises a connection plate, the connection plate is integrally formed on the housing, and a plurality of connection holes are formed on the connection plate, and each of the connection holes has a connection hole thread.

In one embodiment, the converter further comprises at least one waterproof joint, wherein the waterproof joint has a joint surface and a joint thread formed on the joint surface of the waterproof joint, and the joint thread is directly connected to the connection hole thread.

In one embodiment, the connection plate comprises at least two plate ribs, and the connection hole thread is formed between the two plate ribs.

In the embodiments of the invention, while the cover is being rotated from the closed orientation to the open orientation relative to the housing, the connection arm protrusion sequentially abuts the slot abutting portion and then is separated from the slot abutting portion to provide the tactile sense generated to the user. The tactile sense notices the user that the cover is approaching to the predetermined position, the user therefore can prevent from over-rotating the cover, and the connection cable is prevented from being pulled and damaged.

Utilizing the converter of the embodiments of the invention, the connection plate is integrally formed on the housing. A plurality of connection holes are formed on the connection plate, and each of the connection holes has a connection hole thread. Therefore, during assembly of the waterproof joint to the connection plate, no additional nut is required to fasten the waterproof joint, and the waterproof joint can be directly affixed to the connection plate. The assembling process is simplified, and the possible leaking points are reduced, and the waterproofing design is more reliable. In one embodiment, the connection plate comprises a plurality of plate ribs, and the connection hole thread is formed between the two plate ribs (on the inner surface of the two plate ribs). Therefore, there are more connection hole threads, and the strength and connection reliability are improved.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a perspective view of a converter of an embodiment of the invention;

FIG. 2A is an assembled view of the details of the converter of the embodiment of the invention;

FIG. 2B is an exploded view of the details of the converter of the embodiment of the invention;

FIG. 3A is a sectional view showing the details of a shaft and a slot of the converter of the embodiment of the invention, wherein the cover is in a closed orientation relative to a housing;

FIG. 3B is a sectional view showing the details of the shaft and the slot of the converter of the embodiment of the invention, wherein the shaft is moved toward a second shaft position inside the slot;

FIG. 3C is a sectional view showing the details of the shaft and the slot of the converter of the embodiment of the invention, wherein the cover is in an open orientation relative to the housing;

FIG. 4A is a sectional view showing the details of a connection arm protrusion of the embodiment of the invention, wherein the cover is in the closed orientation relative to the housing;

FIG. 4B is a sectional view showing the details of the connection arm protrusion of the embodiment of the invention, wherein the connection arm protrusion abuts the slot abutting portion;

FIG. 4C is a sectional view showing the details of a connection arm protrusion of the embodiment of the invention, wherein the cover is in the open orientation relative to the housing;

FIG. 5A shows a connection plate of an embodiment of the invention;

FIG. 5B shows a waterproof joint of an embodiment of the invention being connected to the connection plate; and

FIG. 5C is a sectional view of the connection plate of an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

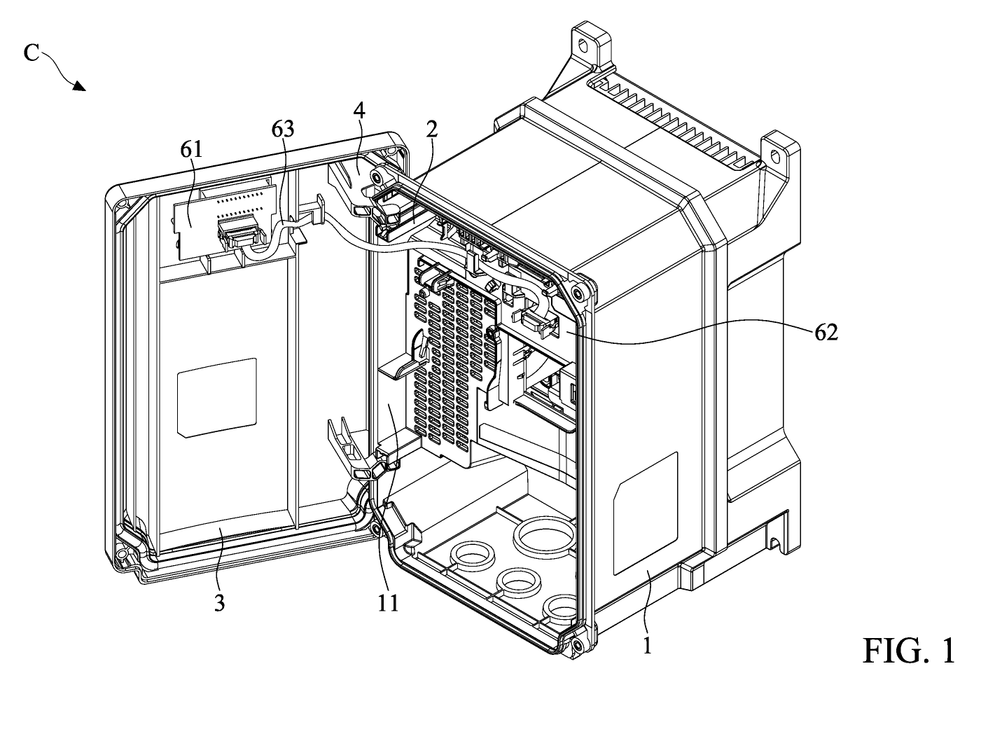

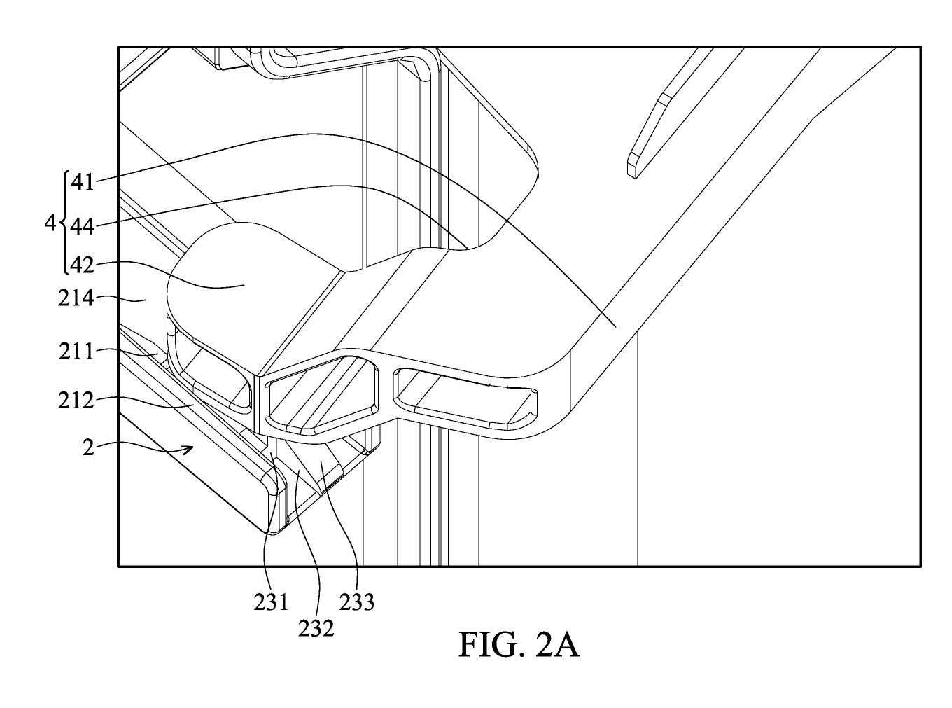

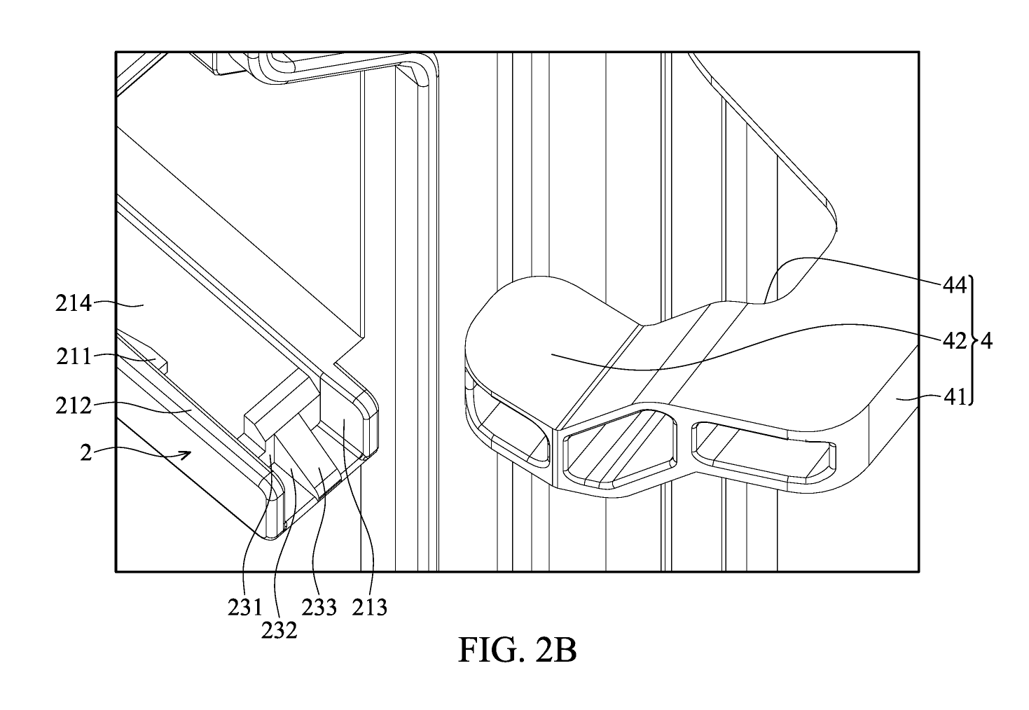

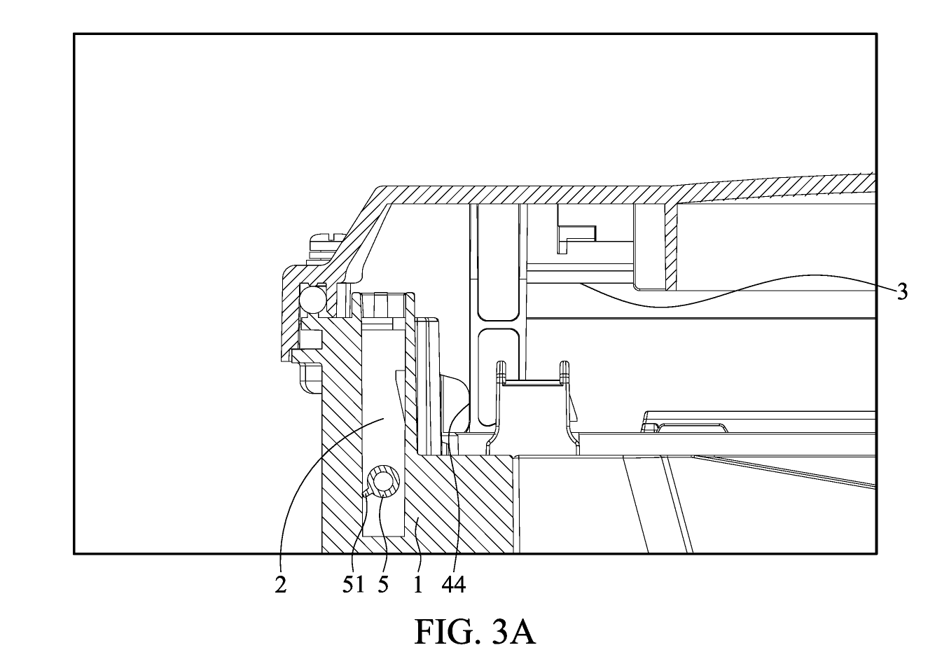

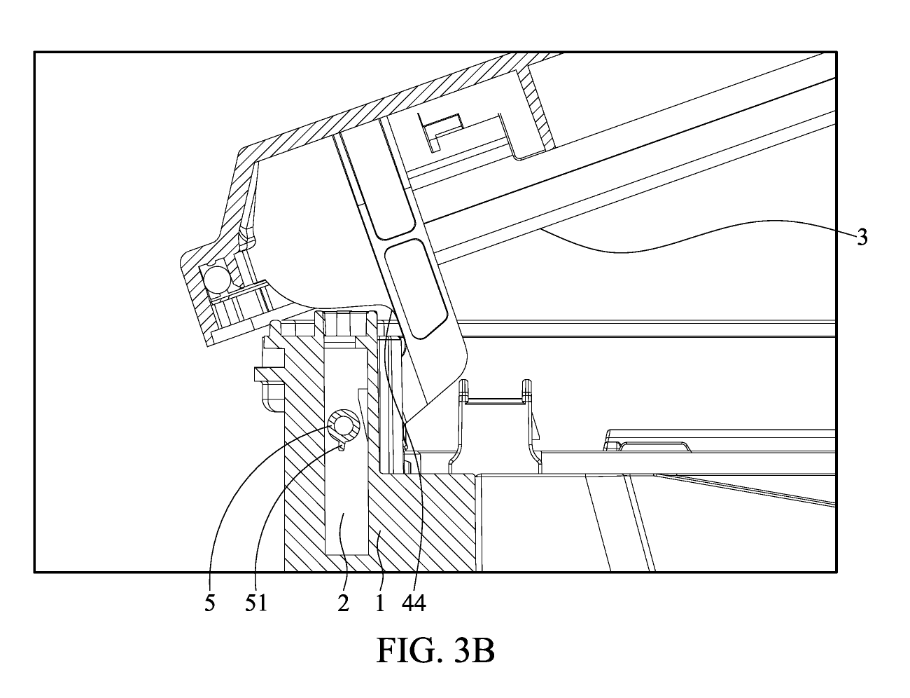

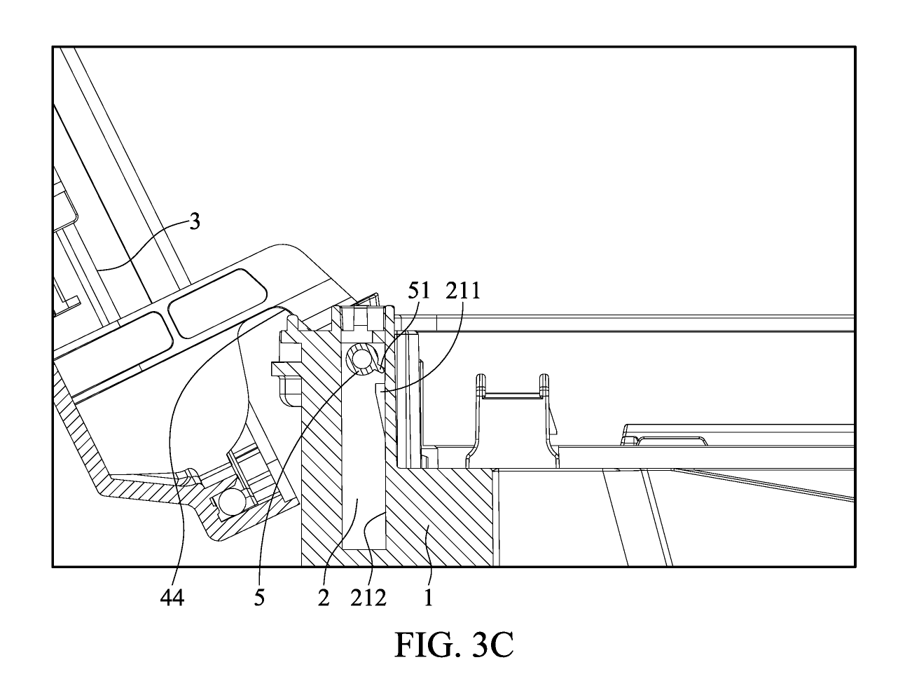

FIG. 1 is a perspective view of a converter C of an embodiment of the invention. FIG. 2A is an assembled view of the details of the converter C of the embodiment of the invention. FIGS. 3A, 3B and 3C are sectional views showing the details of a shaft 5 and a slot 2 of the converter C of the embodiment of the invention, wherein the shaft 5 is in different positions. With reference to FIGS. 1, 2A, 3A, 3B and 3C, the converter C of the embodiment of the invention includes a housing 1, a slot 2, a cover 3, at least a connection arm 4 and a shaft 5. The housing 1 includes a housing inner wall 11. The slot 2 is disposed on the housing inner wall 11. The connection arm 4 is connected to the cover 3. The shaft 5 is disposed on the connection arm 4. The shaft 5 is rotatably connected to the slot 2, and is adapted to slide in the slot 2. In one embodiment, the housing 1 and the cover 3 define a range of the main body of the converter C, and the main body contains electronic elements as shown in FIG. 1.

With reference to FIG. 3A, in one embodiment, when the cover 3 is in a closed orientation which is relative to the housing 1, the shaft 5 is in a first shaft position where is inside the slot 2, and the cover 3 is substantially attached to the housing 1. With reference to FIG. 3C, when the cover 3 is in an open orientation which is relative to the housing 1, the shaft 5 is in a second shaft position where is inside the slot 2, and an included angle is formed between the cover 3 and the housing 1.

With reference to FIGS. 1 and 2A, in one embodiment, the entire slot 2 is inside the housing 1 completely.

FIG. 2B is an exploded view of the details of the converter C of the embodiment of the invention. In one embodiment, the shaft 5 is integrally formed on the connection arm 4.

With reference to FIGS. 3A, 3B and 3C, in one embodiment, the shaft 5 comprises a shaft rib 51. The slot 2 comprises a slot restriction portion 211 and a first slot side wall 212. The slot restriction portion 211 is formed on the first slot side wall 212. When the cover 3 is in the closed orientation relative to the housing 1, the shaft 5 is in the first shaft position inside the slot 2 (as shown in FIG. 3A). Along with a process the cover 3 is opened, the shaft 5 moves continuously in the slot 2 toward the second shaft position, and then passes by the slot restriction portion 211 (as shown in FIG. 3B). Finally, when the cover 3 is in the open orientation relative to the housing 1 (as shown in FIG. 3C), the shaft 5 is in the second shaft position inside the slot 2, the position of the shaft rib 51 corresponds to the slot restriction portion 211, and the slot restriction portion 211 is adapted to abut the shaft rib 51 to restrict the movement (no matter displacement or rotation) of the cover 3. As shown in FIG. 3B, utilizing the slot restriction portion 211 and the shaft rib 51, the cover 3 is prevented from being rapidly rotated or moved by unexpected force, and the structure of the converter C is protected, and the tactile sense generated by relative operation of the slot restriction portion 211 and the shaft rib 51 is provided to the user.

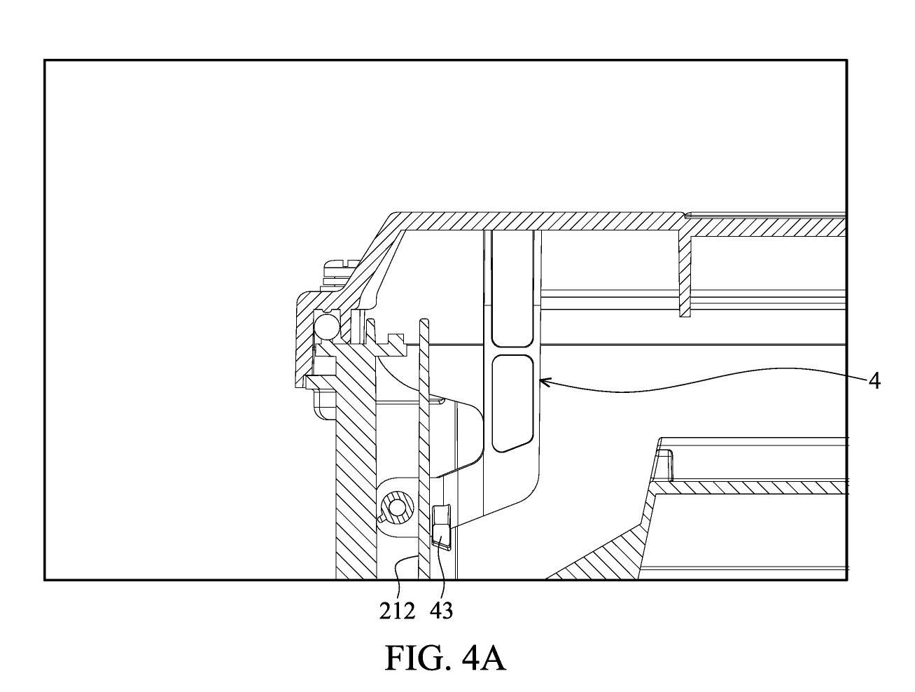

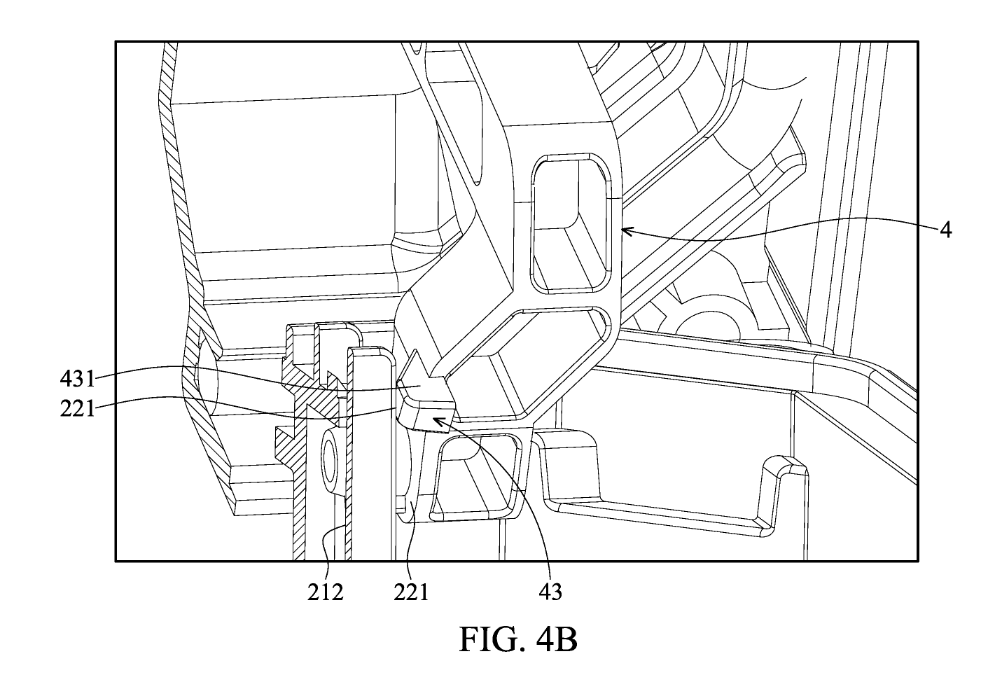

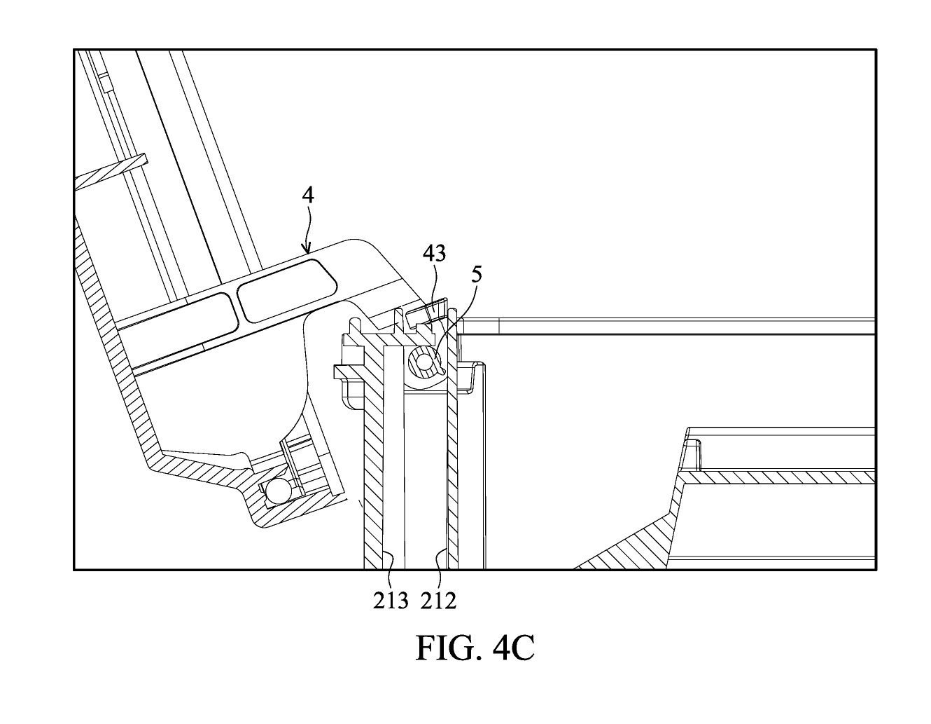

FIGS. 4A, 4B and 4C show the details of a connection arm protrusion of the embodiment of the invention, wherein the connection arm protrusion 43 are in different orientations. With reference to FIGS. 4A, 4B and 4C, in one embodiment, the connection arm 4 comprises the connection arm protrusion 43. The slot 2 comprises a slot abutting portion 221. The slot abutting portion 221 is formed on one end of the first slot side wall 212 (FIGS. 4A and 4B). While the cover 3 is rotating from the closed orientation (FIG. 4A) to the open orientation (FIG. 4C) relative to the housing 1, the connection arm protrusion 43 sequentially abuts the slot abutting portion 221 and then is separated from the slot abutting portion 221 (FIG. 4B) to provide the tactile sense generated to the user. The tactile sense notices the user that the cover 3 is approaching to a predetermined position, and the force provided by the user needs to be moderate, and the structure of the converter C is protected. In this embodiment, the connection arm protrusion 43 comprises a protrusion inclined surface 431. During the movement of the connection arm 4, the connection arm protrusion 43 smoothly passes by the slot abutting portion 221 via the guiding of the protrusion inclined surface 431.

With reference to FIGS. 4A, 4B and 4C, when the cover 3 is in the closed position relative to the housing 1 (FIG. 4A), the first slot side wall 212 is located between the connection arm protrusion 43 and the shaft 5.

When the cover 3 is in the opened position relative to the housing 1 (FIG. 4C), the connection arm protrusion 43 is located between the first slot side wall 212 and a second slot side wall 213 of the slot 2.

With reference to FIGS. 2A, 2B and 4C, in one embodiment, the slot 2 comprises the first slot side wall 212 and the second slot side wall 213 mentioned above, and further comprises a slot stopper 231 and a slot bottom wall 214. The slot stopper 231 is connected to the first slot side wall 212, the second slot side wall 213 and the slot bottom wall 214. The slot stopper 231, the first slot side wall 212, the second slot side wall 213 and the slot bottom wall 214 substantially define a space of the slot 2. When the shaft 5 is disposed in the slot 2, the slot stopper 231 is adapted to restrict the shaft 5 to prevent the shaft 5 from being separated or slipped out from the space of the slot 2.

With reference to FIGS. 2A and 2B, in one embodiment, the slot 2 further comprises a guiding portion 232, and the guiding portion 232 is disposed on the slot stopper 231. In one embodiment, the guiding portion 232 is perpendicular to the slot stopper 231. The guiding portion 232 has a guiding inclined surface 233. While the connection arm 4 is being assembled to the slot 2, the shaft 5 is guided by the guiding inclined surface 233 of the guiding portion 232 to slide into the slot 2 smoothly. In one embodiment, the guiding portion 232 is connected to the slot bottom wall 214. Therefore, the guiding portion 232 increases the strength of the slot stopper 231, and the slot stopper 231 is prevented from being broken due to impact of the shaft 5.

With reference to FIGS. 2A and 2B, in one embodiment, the connection arm 4 comprises a first section part 41 and a second section part 42. The first section part 41 is connected to the second section part 42. A first extending direction of the first section part 41 differs from a second extending direction of the second section part 42. The shaft 5 is disposed on the second section part 42. In this embodiment, the first section part 41 is connected to the second section part 42, and the first extending direction of the first section part 41 differs from the second extending direction of the second section part 42. Therefore, the connection arm 4 has elasticity, and the connection arm 4 is prevented from being broken under unexpected impact.

With reference to FIGS. 2A and 2B, in one embodiment, the connection arm 4 further comprises a guiding curved surface 44, and the guiding curved surface 44 is disposed on the first section part 41. While the cover 3 is being rotated from the open orientation to the closed orientation relative to the housing 1, the guiding curved surface 44 always abuts the housing 1 in the whole operation process. The guiding curved surface 44 guides the cover 3 to be smoothly rotated from the open orientation to the closed orientation, and vice versa, and the user can rotate to close or open the cover 3 smoothly with one hand.

With reference to FIG. 1A, in one embodiment, the converter C further comprises an interface board 61, a mainboard 62 and at least a connection cable 63. The mainboard 62 is disposed in the housing 1, the interface board 61 is affixed to the cover 3, and the interface board 61 is electrically connected to the mainboard 62 via the connection cable 63. In the embodiments of the invention, the interface board 61 is adapted for human-machine communication, such as but not limited to the display panel, the control panel or other panels. In the embodiments of the invention, while the cover 3 is rotating from the closed orientation (FIG. 4A) to the open orientation (FIG. 4C) relative to the housing 1, the connection arm protrusion 43 sequentially abuts the slot abutting portion 221, and then is separated from the slot abutting portion 221 (FIG. 4B) to provide the tactile sense generated to the user. The tactile sense notices the user that the cover 3 is approaching to the predetermined position, the user therefore can prevent from over-rotating the cover 3, and the connection cable 63 is prevented from pulled and damaged. It should be noted that other electronic components should be disposed inside the converter C for normal operations. However, the configuration of the electronic components is not a technical problem to be solved by the invention, and thus the related description is omitted.

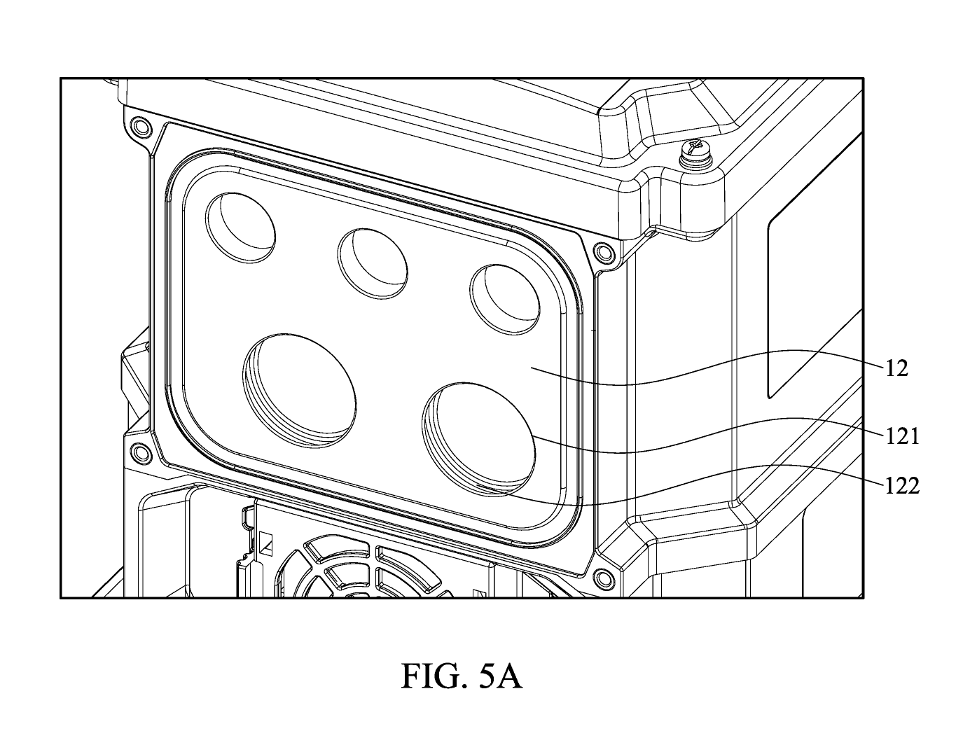

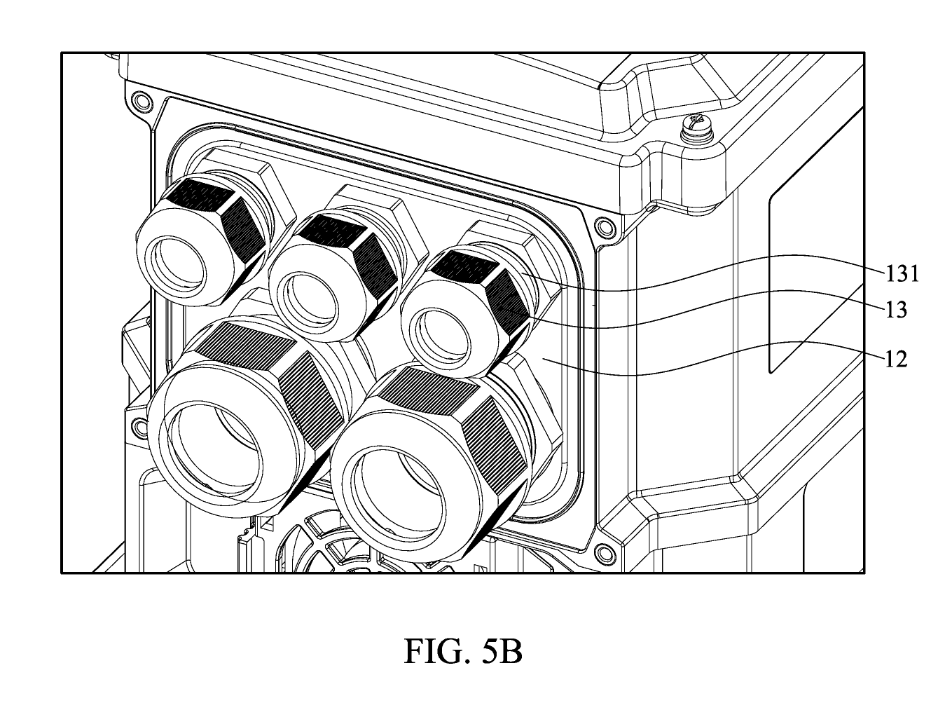

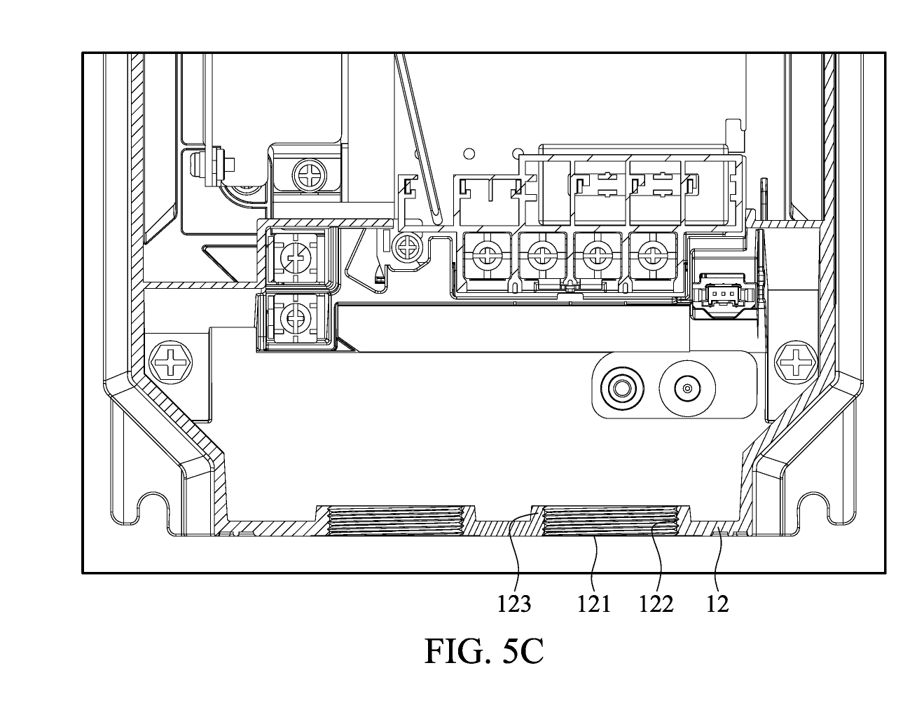

FIG. 5A shows a connection plate of an embodiment of the invention. With reference to FIGS. 1 and 5A, in one embodiment, the housing 1 comprises a connection plate 12, and the connection plate 12 is integrally formed on the housing 1. A plurality of connection holes 121 are formed on the connection plate 12, and each of the connection holes 121 has a connection hole thread 122.

FIG. 5B shows a waterproof joint of an embodiment of the invention being connected to the connection plate. FIG. 5C is a sectional view of the connection plate of an embodiment of the invention. With reference to FIGS. 5B and 5C, in one embodiment, the converter C further comprises at least one waterproof joint 13, wherein the waterproof joint 13 has a joint surface and a joint thread 131 formed on the joint surface, and the joint thread 131 is directly connected to the corresponding connection hole thread 122.

With reference to FIGS. 1, 5A, 5B and 5C, utilizing the converter C of the embodiment of the invention, the connection plate 12 is integrally formed on the housing 1. A plurality of connection holes 121 are formed on the connection plate 12, and each of the connection holes 121 has a connection hole thread 122. Therefore, during assembly of the waterproof joint 13 to the connection plate 12, no additional nut is required to fasten the waterproof joint 13, and the waterproof joint 13 can be directly affixed to the connection plate 12. The assembling process is simplified, and the possible leaking point is reduced due to the decreased members, and the waterproofing design is more reliable. With reference to FIG. 5C, in one embodiment, the connection plate 12 comprises a plurality of plate ribs 123, and the connection hole thread 122 is defined and formed between two of the plate ribs 123 (i.e., on the inner surface of the plate ribs 123). Therefore, there are more connection hole threads 122, and the strength and connection reliability are improved.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A converter, comprising:
a housing, comprising a housing inner wall;
a slot, disposed on the housing inner wall;
a cover;
a connection arm, connected to the cover; and
a shaft, disposed on the connection arm, wherein the shaft is rotatably connected to the slot, and is adapted to slide in the slot.

2. The converter as claimed in claim 1, wherein when the cover is in a closed orientation relative to the housing, the shaft is in a first shaft position inside the slot, and when the cover is in an open orientation relative to the housing, the shaft is in a second shaft position inside the slot.

3. The converter as claimed in claim 1, wherein the slot is inside the housing completely.

4. The converter as claimed in claim 1, wherein the shaft is integrally formed on the connection arm.

5. The converter as claimed in claim 2, wherein the shaft comprises a shaft rib, the slot comprises a slot restriction portion, and when the cover is in the open orientation relative to the housing, the shaft is in the second shaft position inside the slot, and the slot restriction portion is adapted to abut the shaft rib to restrict movement of the cover.

6. The converter as claimed in claim 2, wherein the connection arm comprises a connection arm protrusion, the slot comprises a slot abutting portion, and while the cover is being rotated from the closed orientation to the open orientation relative to the housing, wherein the connection arm protrusion sequentially abuts the slot abutting portion and is separated from the slot abutting portion.

7. The converter as claimed in claim 2, wherein the slot comprises a slot stopper, a first slot side wall, a second slot side wall and a slot bottom wall, the slot stopper is connected to the first slot side wall, the second slot side wall and the slot bottom wall, and when the shaft is disposed in the slot, the slot stopper is adapted to restrict the shaft to prevent the shaft from being out from the slot.

8. The converter as claimed in claim 7, wherein the slot further comprises a guiding portion, the guiding portion is disposed on the slot stopper and perpendicular to the slot stopper, the guiding portion has a guiding inclined surface, and during assembly, the shaft is guided by the guiding inclined surface to slide into the slot.

9. The converter as claimed in claim 2, wherein the connection arm comprises a first section part and a second section part, the first section part is connected to the second section part, wherein a first extending direction of the first section part differs from a second extending direction of the second section part, and the shaft is disposed on the second section part.

10. The converter as claimed in claim 9, wherein the connection arm further comprises a guiding curved surface, the guiding curved surface is disposed on the first section part, and while the cover is being rotated from the open orientation to the closed orientation relative to the housing, wherein the guiding curved surface abuts the housing.

11. The converter as claimed in claim 1, further comprising an interface board, a mainboard and a connection cable, wherein the mainboard is disposed in the housing, the interface board is affixed to the cover, and the interface board is electrically connected to the mainboard via the connection cable.

12. The converter as claimed in claim 1, wherein the housing further comprises a connection plate, the connection plate is integrally formed on the housing, and a plurality of connection holes are formed on the connection plate, and each of the connection holes has a connection hole thread.

13. The converter as claimed in claim 12, further comprising at least one waterproof joint, wherein the waterproof joint has a joint surface and a joint thread formed on the joint surface, and the joint thread is directly connected to the connection hole thread.

14. The converter as claimed in claim 12, wherein the connection plate comprises at least two plate ribs, and the connection hole thread is formed between the two plate ribs.
